(19) United States
(12) Patent Application Publication
(10) Pub. No.: US 2007/0284650 A1
(43) Pub. Date: Dec. 13, 2007

(54) Memory device and a method of forming a memory device

(76) Inventor: Josef Willer, Riemerling (DE)

Correspondence Address: EDELL, SHAPIRO & FINNAN, LLC, 1901 RESEARCH BLVD., SUITE 400, ROCKVILLE, MD, 20850, US

(21) Appl. No.: 11/448,134

(22) Filed: Jun. 7, 2006

(51) Int. Cl. H01L 29/792; H01L 21/336

(52) U.S. Cl. 257/324; 438/287; 257/E29.309

(57) ABSTRACT

A memory device includes active regions extending in a first direction, the active regions being formed in a semiconductor substrate. Transistors are formed in the active regions, including a first and a second source/drain region, a channel formed between the first and the second source/drain region, a gate electrode, and a charge storage layer stack disposed between the gate electrode and the channel, where adjacent active regions are isolated from each other by fin isolation grooves. Wordlines extend in a second direction, and each wordline is connected with a plurality of gate electrodes that are assigned to different active regions. The active regions are formed as ridges in the semiconductor substrate, with the word lines and the charge storing layer stack being disposed adjacent to at least two sides of each of the active regions. Each of the ridges has a top portion and a bottom portion, where the maximum width of the top portion is larger than the minimum width of the bottom portion.

### TECHNICAL FIELD

The present invention refers to a memory device as well as to a method of forming a memory device.

### BACKGROUND

Non-volatile memory cells (NVM) are gaining increasing importance in the field of multimedia applications. For example, non-volatile memories are contained in cell phones, digital cameras, and other applications. In particular, the commonly used non-volatile flash memory cells can be based on the floating gate technology or on the charge trapping device technology. A cross-sectional view of a flash memory cell being based on the charge trapping device technology is, for example, shown in FIG. 1A.

The non-volatile memory device shown in FIG. 1A is based on the SONOS technology. FIG. 1A shows a cross-sectional view of a SONOS cell between IV and IV as is shown in FIG. 1B, for example. In particular, the SONOS cell is an n-channel MOSFET device 28, wherein the gate dielectric is replaced with a storage layer stack 26. As is shown in FIG. 1A, the storage layer stack 26 is disposed above the channel 27 and under the gate electrode 4. The storage layer stack 26 typically includes a charge trapping layer 262, which, for example, may be a silicon nitride layer. A lower boundary layer 261 is disposed beneath the charge trapping layer. An upper boundary layer 263 is disposed above the charge trapping layer. The upper and lower boundary layers sandwich the charge trapping layer 262. The upper and lower boundary layers 261, 263 have a thickness larger than 2 nm to avoid any direct tunnelling. The first and second source/drain portions 37, 38 are implemented as the doped regions 35. Depending on the architecture and the programming mechanisms of a memory device comprising a plurality of memory cells of the type illustrated in FIG. 1A, the memory device is referred to as a SONOS or an NROM memory device.

The SONOS cell is programmed by Fowler-Nordheim-Tunneling (FNT), for example, and erasing is accomplished by Fowler-Nordheim-Tunneling by applying appropriate voltages to the corresponding bitlines and wordlines, respectively. Due to the charge trapped in the charge storage layer, the threshold voltage of the transistor is changed. By applying appropriate voltages to the corresponding wordlines and bitlines the changed threshold voltage and, thus, the stored information is detected.

Typically, the flash memories can be divided into NOR-type structures and NAND-type structures. In the NOR-type structure, cells are disposed in parallel between a bitline and a ground. In the NAND-type structure, cells are disposed in series between a bitline and a ground.

A plan view of an exemplary NAND-type memory cell array is shown in FIG. 1B. Active regions 21 are formed in a semiconductor substrate 1 and isolated from each other by deep isolation trenches 33 (STI, “Shallow Trench Isolation”) which are filled with an insulating material, in particular, silicon dioxide. Bitlines 50 are formed parallel to the active regions 21. Moreover, wordlines 40 are formed so as to cross the active regions 21. In each of the active regions a plurality of transistors is formed, the transistors being connected in series. The conductivity of each of the transistors is controlled by activating a corresponding wordline 40. A common source line 44 is provided so as to connect the active regions 21.

Moreover, FIG. 2 shows a schematic plan view of a NOR-type cell architecture. The memory cells are arranged in rows, two memory cells of one row being connected with a common source line 45 or with one common bitline contact 51. The wordlines 40 are formed so as to extend perpendicularly with respect to the rows of memory cells. Bitlines are arranged parallel to the active regions 21. The bitlines are connected with the active regions via a bitline contact 51.

### SUMMARY

According to the invention, a memory device comprises a plurality of active regions extending in a first direction, each of the active regions being formed in a semiconductor substrate, transistors being formed in the active regions, the transistors comprising a first and a second source/drain region, a channel formed between the first and the second source/drain region and a gate electrode, a charge storage layer stack being disposed between the gate electrode and the channel, adjacent ones of the active regions being isolated from each other by a fin isolation groove, a plurality of wordlines extending in a second direction, the second direction intersecting the first direction, each of the wordlines being connected with a plurality of gate electrodes which are assigned to different active regions, wherein the active regions are formed as ridges in the semiconductor substrate, the word lines and the charge storing layer stack being disposed adjacent to at least two sides of each of the active regions. Each of the ridges includes a top portion and a bottom portion, the bottom portion being disposed beneath the top portion, the top portion having a maximum width measured in a direction perpendicular to the first direction, and the bottom portion having a minimum width measured in a direction perpendicular to the first direction, wherein the maximum width of the top portion is larger than the minimum width of the bottom portion.

Moreover, according to the invention, a memory device comprises a plurality of active regions extending in a first direction, each of the active regions being formed in a semiconductor substrate, transistors being formed in the active regions, the transistors comprising a first and a second source/drain region, a channel formed between the first and the second source/drain region and a gate electrode, a charge storage layer stack being disposed between the gate electrode and the channel, adjacent ones of the active regions being isolated from each other by a fin isolation groove, and a plurality of wordlines extending in a second direction, the second direction intersecting the first direction, each of the wordlines being connected with a plurality of gate electrodes which are assigned to different active regions. The active regions are formed as ridges in the semiconductor substrate, the word lines and the charge storing layer stack being disposed adjacent to at least two sides of each of the active regions, wherein each of the ridges comprises a righthand and a lefthand sidewalls, an angle α between the righthand sidewall and the substrate surface being 90° or less, the angle α being measured in the upper half of the ridge, an angle β between the lefthand sidewall and the substrate surface being 90° or more, the angle β being measured in the upper half of the ridge, the height of the ridge being measured from the bottom surface of the fin isolation groove to the upper surface of the ridge.

In addition, a memory device comprises a plurality of active regions extending in a first direction, each of the active regions being formed in a semiconductor substrate, transistors being formed in the active regions, the transistors comprising a first and a second source/drain region, a channel formed between the first and the second source/drain region and a gate electrode, a charge storage layer stack being disposed between the gate electrode and the channel, adjacent ones of the active regions being isolated from each other by a fin isolation groove, a plurality of wordlines extending in a second direction, the second direction intersecting the first direction, each of the wordlines being connected with a plurality of gate electrodes which are assigned to different active regions, wherein the active regions are formed as ridges in the semiconductor substrate, the word lines and the charge storing layer stack being disposed adjacent to at least two sides of each of the active regions, wherein each of the ridges comprises an upper surface and two sidewalls in a cross-section perpendicularly with respect to the first direction, each of the sidewalls comprising at least one curved surface having a center of curvature lying within the semiconductor substrate in a plane perpendicularly with respect to the substrate surface and perpendicularly to the first direction.

According to the invention, a memory device comprises a plurality of active regions extending in a first direction, each of the active regions being formed in a semiconductor substrate, transistors being formed in the active regions, the transistors comprising a first and a second source/drain region, a channel formed between the first and the second source/drain region, a gate electrode and means for changing the threshold voltage of the transistor by storing a charge, means for addressing the gate electrodes, means for isolating adjacent active regions from each other, each of the active regions comprising means for enlarging the width in the upper portion of the active region with respect to the width in the lower portion of the active regions.

A method of forming a memory device according to the invention comprises providing a semiconductor substrate including a surface, defining grooves extending in a first direction, thereby defining active regions, each of the grooves comprising sidewalls and a bottom portion, covering the sidewalls of the grooves with a cover layer, providing an insulating layer on the bottom portion of each of the grooves, removing the cover layer from the sidewalls of the grooves, providing a storage layer stack, the storage layer stack being adjacent to the sidewalls of the grooves and to the surface of each of the active regions, the storage layer stack covering the insulating layer, providing a word line layer stack comprising at least one conductive layer, patterning the word line layer stack as well as the storage layer stack so as to form single word lines, thereby providing uncovered portions of the active regions, and providing doped portions in each of the active regions, thereby forming first and second source/drain regions.

According to the invention, a method of manufacturing a NAND-type non-volatile memory device comprises providing a semiconductor substrate including a surface, defining grooves extending in a first direction, thereby defining active regions, each of the grooves comprising sidewalls and a bottom portion, covering the sidewalls of the grooves with a cover layer, providing an insulating layer on the bottom portion of each of the grooves, removing the cover layer from the sidewalls of the grooves, providing a storage layer stack, the storage layer stack being adjacent to the sidewalls of the grooves and to the surface of each of the active regions, the storage layer stack covering the insulating layer, the storage layer stack comprising a charge trapping layer and a top layer, removing the charge trapping layer and the top layer from the final regions of each of the active regions, providing a word line layer stack comprising at least one conductive layer, patterning the word line layer stack as well as the storage layer stack so as to form single word lines, thereby providing uncovered portions of the active regions, and providing doped portions in each of the active regions, thereby forming first and second source/drain regions.

The above and still further features and advantages of the present invention will become apparent upon consideration of the following detailed description of exemplary embodiments thereof, wherein like numerals define like components in the drawings.

### BRIEF DESCRIPTION OF THE DRAWINGS

FIG. 1A depicts a cross-sectional view of an exemplary memory cell.

FIG. 1B depicts a plan view of a conventional memory cell array.

FIG. 2 depicts a plan view of another conventional memory cell array.

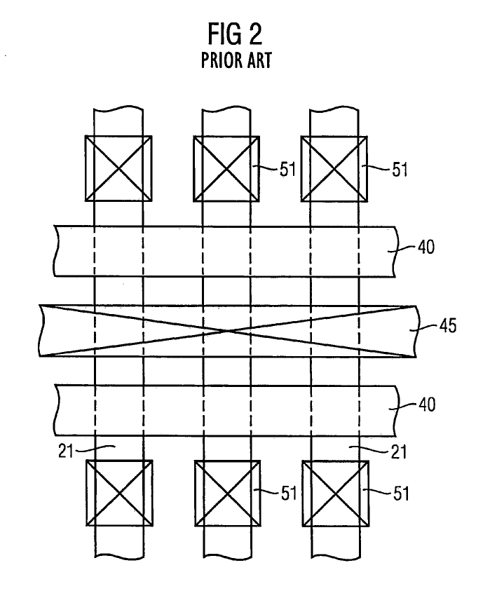

FIG. 3 depicts a cross-sectional view of a semiconductor substrate after defining the active regions 31 in accordance with the invention.

FIG. 4 depicts a cross-sectional view of the substrate of FIG. 3 after forming layers.

FIG. 5 depicts a cross-sectional view of the substrate of FIG. 4 after performing a further processing step.

FIG. 6 depicts a cross-sectional view of the substrate of FIG. 5 after depositing a storage layer stack.

FIG. 7A depicts a plan view of the processed substrate of the invention.

FIG. 7B depicts a cross-sectional view of the substrate of the invention after performing a further processing step.

FIG. 8 depicts a cross-sectional view of the substrate of FIG. 7B after depositing a wordline layer stack.

FIG. 9 depicts a cross-sectional view of the substrate of FIG. 8 after etching back the wordline layer stack.

FIG. 10A depicts a cross-sectional view of the substrate of FIG. 9 after performing an ion implantation step;

FIG. 10B depicts another cross-sectional view of the wordlines after performing the ion implantation step.

FIG. 11A depicts a cross-sectional view of the substrate of FIG. 10A after etching back the polysilicon layer.

FIG. 11B depicts a cross-sectional view of the substrate of FIG. 10A after etching back the polysilicon layer.

FIG. 12A depicts a perspective view of a semiconductor substrate according to the invention.

FIG. 12B depicts cross-sectional views of the semiconductor substrate of FIG. 12A.

FIG. 13 depicts a cross-sectional view of a substrate according to a further embodiment of the present invention.

FIG. 14 depicts a cross-sectional view of the substrate of FIG. 13 after extending the openings.

FIG. 15 depicts a cross-sectional view of the substrate after performing an oxidation step.

FIG. 16 depicts a cross-sectional view of the substrate of FIG. 15 after removing the silicon nitride layer.

FIG. 17 depicts a cross-sectional view of the substrate of FIG. 16 after depositing a wordline layer stack.

FIG. 18 depicts a cross-sectional view of a substrate according to a further embodiment of the present invention.

FIG. 19 depicts a cross-sectional view of the substrate of FIG. 18 after depositing the wordline layer stack.

FIG. 20 depicts a schematic cross-sectional view of a completed memory device in accordance with the invention along the direction of the active regions.

FIG. 21 depicts a schematic plan view of a memory device according to another embodiment of the present invention.

FIG. 22 depicts a plan view of a substrate surface after performing a first processing step of a method of another embodiment of the present invention.

FIG. 23 depicts a perspective view of a memory device according to an embodiment of the invention.

### DETAILED DESCRIPTION

The accompanying drawings are included to provide a further understanding of the present invention and illustrate the embodiments of the present invention together with the description to explain the principles of the invention. Other embodiments of the present invention and many of the intended advantages of the present invention will be readily appreciated, as they become better understood by reference to the following detailed description. The elements of the drawings are not necessary to scale relative to each other. Like reference numerals designate corresponding similar parts.

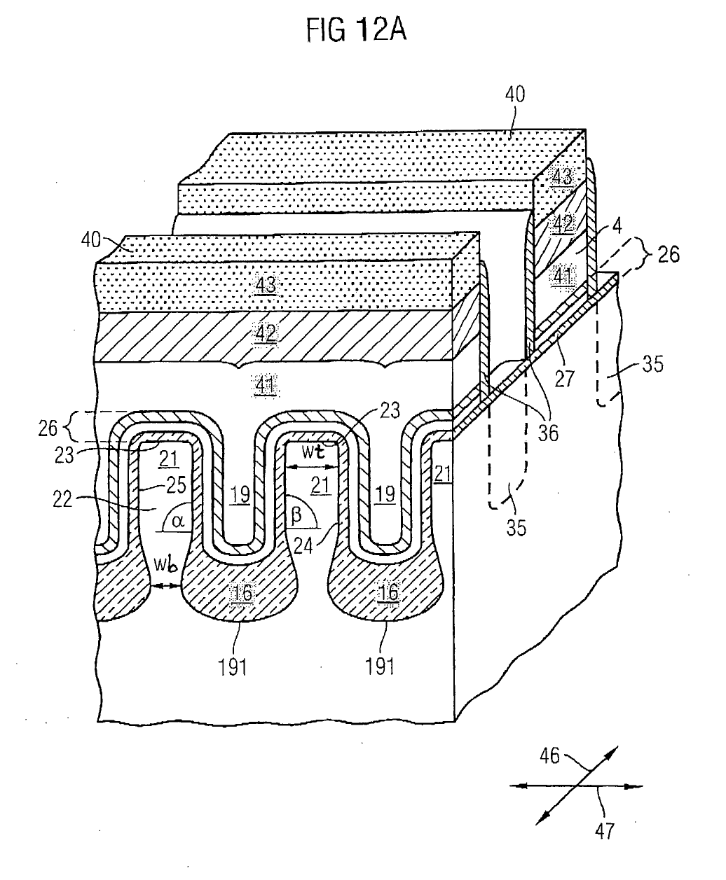

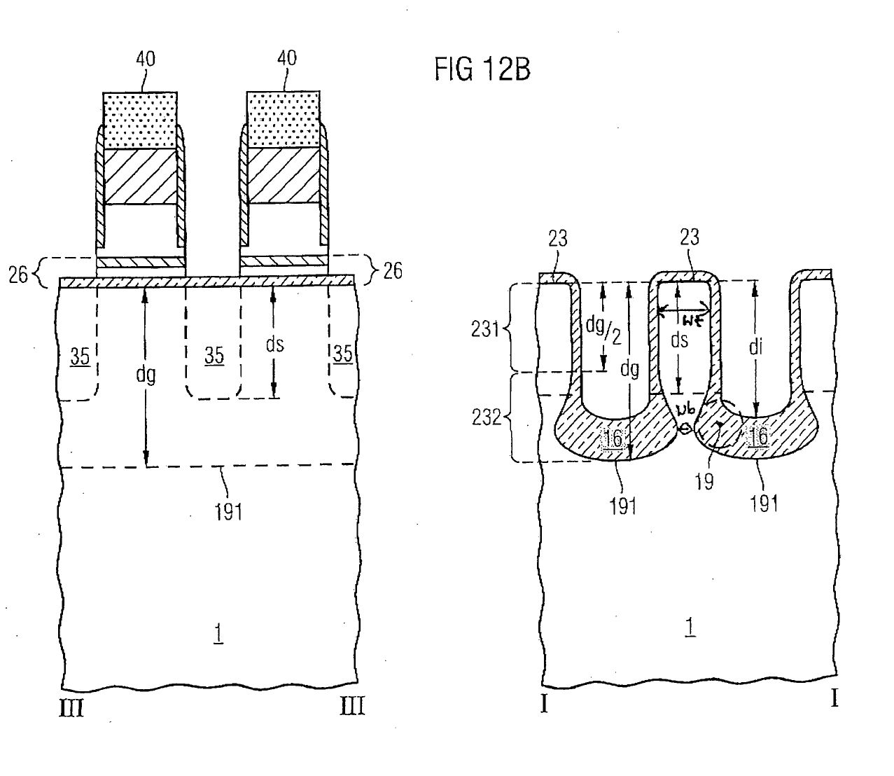

FIG. 12A shows a perspective view of the memory cell device of the present invention. In FIG. 12A, the planarizing layers between adjacent wordlines are omitted, for the sake of convenience. As can be seen, active regions 21 extend in a first direction 46. The active regions 21 are isolated from each other by fin isolation grooves 19. The fin isolation grooves 19 also extend in the first direction 46. In the lower portion of each of the fin isolation grooves, a thick silicon dioxide layer 16 is disposed so as to electrically insulate adjacent active regions 21 from each other. Wordlines 40 extend in a second direction 47. Doped portions 35 are disposed between adjacent wordlines 40. The doped portions 35 form the first and second source/drain portion 37, 38 of the completed transistor. A channel is formed between two adjacent doped portions 35, the conductivity of the channel being controlled by the corresponding gate electrode 4. The storage layer stack 26 is disposed between the channel 27 and the corresponding gate electrode 4. A charge stored in the storage layer stack determines the threshold voltage of the transistor. Accordingly, a charge trapped in the charge storage layer stack 26 can be detected by applying corresponding voltages to the doped portions and the gate electrode, respectively.

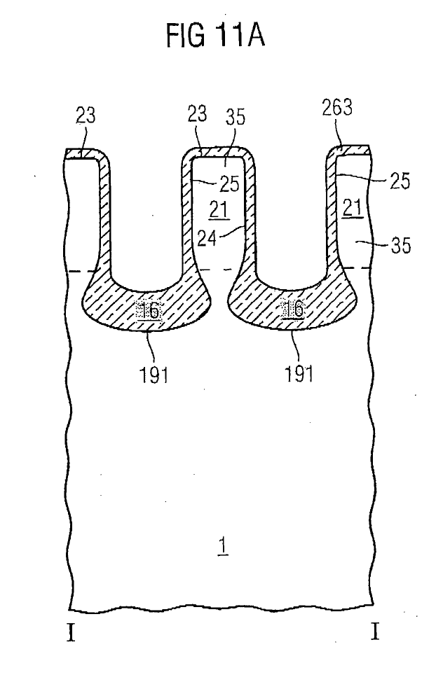

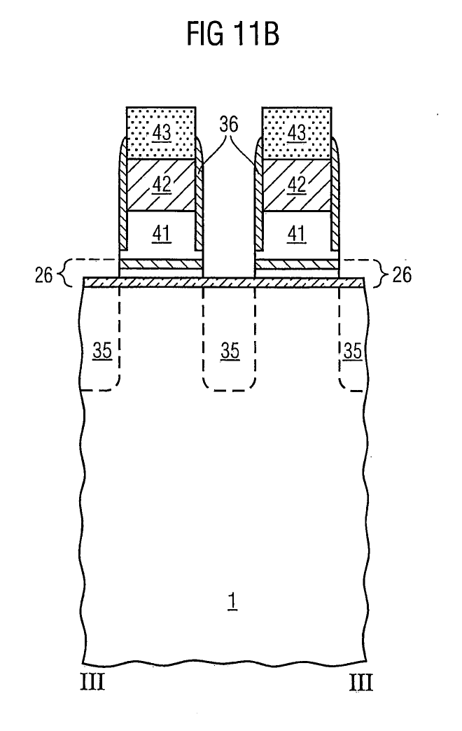

FIG. 12B shows further details of the cross-sectional views shown in FIGS. 11A and 11B, respectively. As can be seen, each of the ridges shown in FIG. 12B includes a top portion 231 and a bottom portion 232. The bottom portion 232 is disposed beneath the top portion 231. The top portion has a maximum width wt and the bottom portion have a minimum width wb, measured in a direction perpendicularly to the first direction, respectively. The maximum width wt of the top portion is larger than the minimum width wb of the bottom portion. The depth dg of each of the fin isolation grooves 19 may, for example, be 90 to 200 nm, or 90 to 130 nm. The depth dg is measured from the upper surface 23 of each of the ridges to the bottom surface 191 of the fin isolation groove 19. For example, the top surface 192 of the insulating material of the fin isolating grooves may be disposed at a depth di, wherein di>0.5×dg, the depth dg being measured from the upper surface 23 of each of the ridges, the fin isolating groove having a depth dg which is measured from the upper surface 23 of each of the ridges to the bottom surface 191 of each of the ridges. For example, the doped portions 35 may extend from the upper surface 23 of each of the ridges to a depth ds, wherein ds>0.3×dg. For example, the depth ds may be more than 0.6×dg. Accordingly, the doped portions 35 are disposed adjacent to the substrate surface 10. In addition, they extend to a very deep depth, as can be seen from the left hand portion of FIG. 12B. As can be seen from the right hand portion of FIG. 12A, for example, the doped portion extends to at least a depth, at which the width of the active region 21 is decreasing. Accordingly, the entire channel is connected with the first and second source/drain region so that the contact has a low contact resistance.

As is shown in FIG. 12A, each of the ridges comprises righthand and lefthand sidewalls, wherein an angle α between the righthand sidewall 24 and the substrate surface 10 is 90° or less, wherein the angle α is measured in the upper half portion 231 of the ridge. Moreover, an angle β between the lefthand sidewall 25 and the substrate surface 10 may be 90° or more, the angle β being measured in the upper half portion 231 of each of the ridges. In this respect, the height of the ridge is measured from the bottom surface of the fin isolation groove to the upper surface 23 of the ridge. The upper half portion of the ridge refers to the portions which is disposed at a height of more than 0.5× the height of the ridge, measured from the upper surface 23 of the ridge. As can also be seen from FIG. 12B, each of the ridges 21 comprises an upper surface 23 and two sidewalls 24, 25 in a cross section, which is taken perpendicularly with respect to the first direction 26. Each of the sidewalls 24, 25 comprises at least one curved surface having a center of curvature 193 which lies within the semiconductor substrate in a plane which is taken perpendicularly with respect to the substrate surface 10 and perpendicularly to first direction 26.

A starting point for performing the method of forming a memory device according to the present invention is a semiconductor substrate, in particular, a silicon substrate, which may for example be p-doped. On the surface 10 of the semiconductor substrate 1, first a thin silicon dioxide layer (pad oxide) having a thickness of approximately 3 to 5 nm is deposited, followed by a first hardmask layer which may be made of silicon nitride having a thickness of approximately 15 to 30 mm. These layers can be deposited by known methods. Thereafter, the active transistor areas are defined by provided field isolation trenches. These field isolation trenches may have a depth of approximately 300 nm. For defining these field isolation trenches (STI) the silicon nitride hardmask layer 12 is patterned, followed by an RIE (Reactive Ion Etching) step for etching silicon to a depth of approximately 300 nm. Thereafter, the trenches are filled with a silicon dioxide material and a CMP (chemical mechanical polishing) step is performed.

In the next step the active regions 21 in which the transistors are to be formed are defined by forming openings 13 in the silicon substrate 1. Accordingly, the hardmask layer 12 is correspondingly patterned. For example, a photoresist material may be deposited and patterned using a mask having a lines/spaces pattern. For example, the lines and spaces may have a width of 40 nm. Nevertheless any other suitable value of the lines width and the spaces width may be chosen. Accordingly, after transferring the photoresist pattern into the hardmask layer 12, lines of silicon nitride having a width of 40 nm and having a distance of 40 nm from each other are defined in the hardmask layer 12. Thereafter, a further reactive ion etching step is performed so as to etch the silicon substrate anisotropically. Thereby, openings 13 are formed in the semiconductor substrate 1. For example, the openings 13 can have a depth of 80 nm, this depth being measured from the surface 10 of the semiconductor substrate 1.

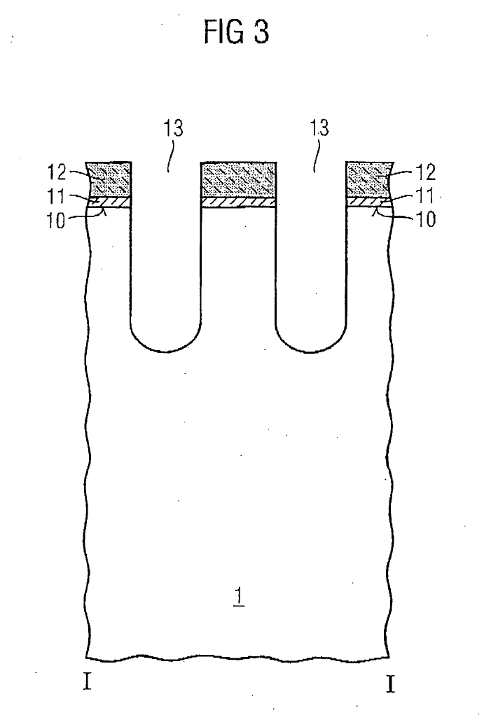

The resulting structure is shown in FIG. 3. As can be seen, openings 13 are formed in the surface 10 of the semiconductor substrate 1. Ridges of silicon are disposed between adjacent openings 13.

Next, an oxidation step is performed so as to grow a sacrificial oxide layer 14 on the resulting surface. For example, several steps of growing and removing a sacrificial oxide layer can be performed. Finally, a sacrificial oxide layer 14 having a thickness of approximately 3 to 10 nm is left on the exposed silicon portions. Thereafter, a silicon nitride layer is conformally deposited so that horizontal and vertical portions of the silicon nitride layer are formed. Thereafter, a reactive ion etching step is performed so as to remove the horizontal portions of the silicon nitride layer. Thereby, silicon nitride spacers 15 are formed on the sidewalls of the openings 13. For example, the silicon nitride spacer 15 may have a thickness of approximately 4 to 8 nm.

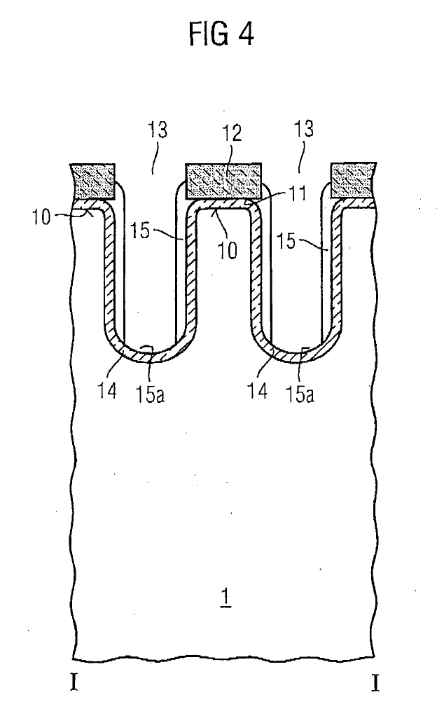

As a result, the structure shown in FIG. 4 is obtained. As can be seen, openings 13 are formed in the surface 10 of the semiconductor substrate 1. The surface of each of the openings 13 is covered with a sacrificial oxide layer 14. On the sidewalls of each of the openings, silicon nitride spacers 15 are provided. Accordingly, in the bottom portion of each of the openings 13 an exposed surface portion 15a is provided, in which the surface of the opening is only covered with a silicon dioxide layer 14. The remaining portions of the substrate surface are covered with the silicon nitride layers 12, 15.

Thereafter, an oxidation step is performed so as to provide a silicon dioxide layer at the uncovered silicon dioxide portions 15a. For example, a thermal oxidation step may be performed. Such a thermal oxidation step is generally known to the person skilled in the art. Due to this thermal oxidation step, part of the silicon substrate is used up for forming the silicon dioxide layer. As a result, each of the active regions 21 becomes more narrow at the lower portion thereof. To be more specific, the active regions become more narrow at a portion at which the silicon dioxide is thermally grown.

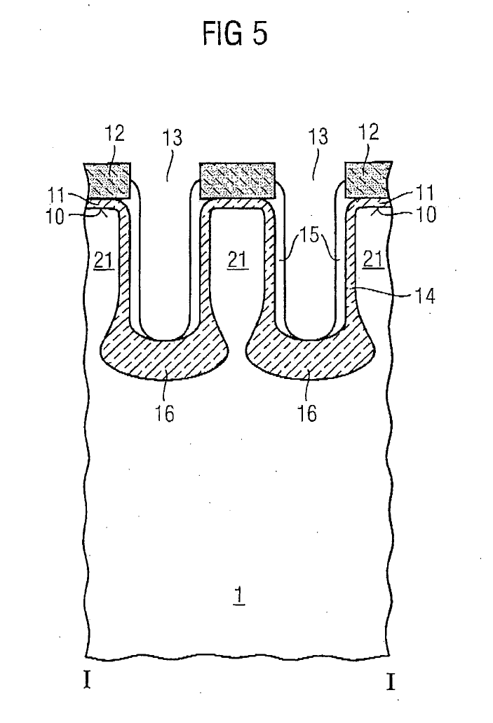

The resulting structure is shown in FIG. 5. In particular, at the bottom portion of each of the openings 13 a thick silicon dioxide layer 16 is formed. In addition, the sidewalls of the openings 13 remain unchanged. The silicon dioxide portions 16 have a lateral extension so that the width of each of the active regions 31 is made very narrow in the lower portion thereof.

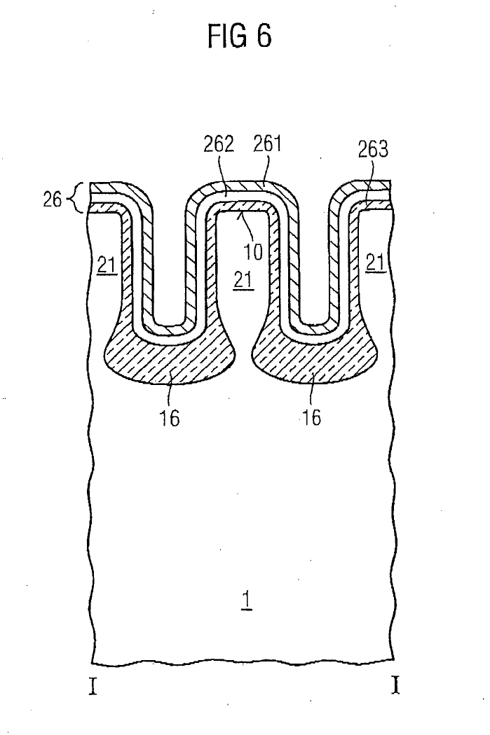

In the next step, the silicon nitride layers 12, 15 are removed via a wet chemical etch. Thereafter, optionally, implantation steps may be performed, so as to provide certain well or channel dopings. Thereafter, the thin sacrificial oxide layer 14 is removed. Optionally, a further thermal oxidation step may be performed, followed by a step of removing the grown oxide layer, so as to thin the active region 21. Thereafter, the storage layer stack of the memory device is provided by generally known methods. In particular, the layers may be grown by a thermal oxidation step or may be deposited in a conventional manner. For example, such a storage layer stack 26 may comprise a lower boundary layer or layer stack, a charge trapping layer and an upper boundary layer. The function of the lower and upper boundary layer stack or layer is to avoid that a charge trapped in the charge trapping layer is unintentionally released from the charge trapping layer. For example, the lower boundary layer may be a silicon dioxide layer 263, having a thickness of approximately 3.5 nm. The charge trapping layer may be a silicon nitride layer 262 having a thickness of approximately 5 nm. The upper boundary layer may be again a silicon dioxide layer 261 having a thickness of approximately 5 nm. Nevertheless, as is generally known, the lower boundary layer may as well be a silicon dioxide layer having a thickness of 4 nm, whereas the upper boundary layer stack can be made of an Al₂O₃ layer having a thickness of approximately 15 nm, followed by a TaN electrode or a gate electrode made of another suitable material, for example, a material having a high workfunction. As a further modification, the lower boundary layer stack may comprise various silicon dioxide and silicon nitride layers so as to avoid direct tunneling. The resulting structure is shown in FIG. 6.

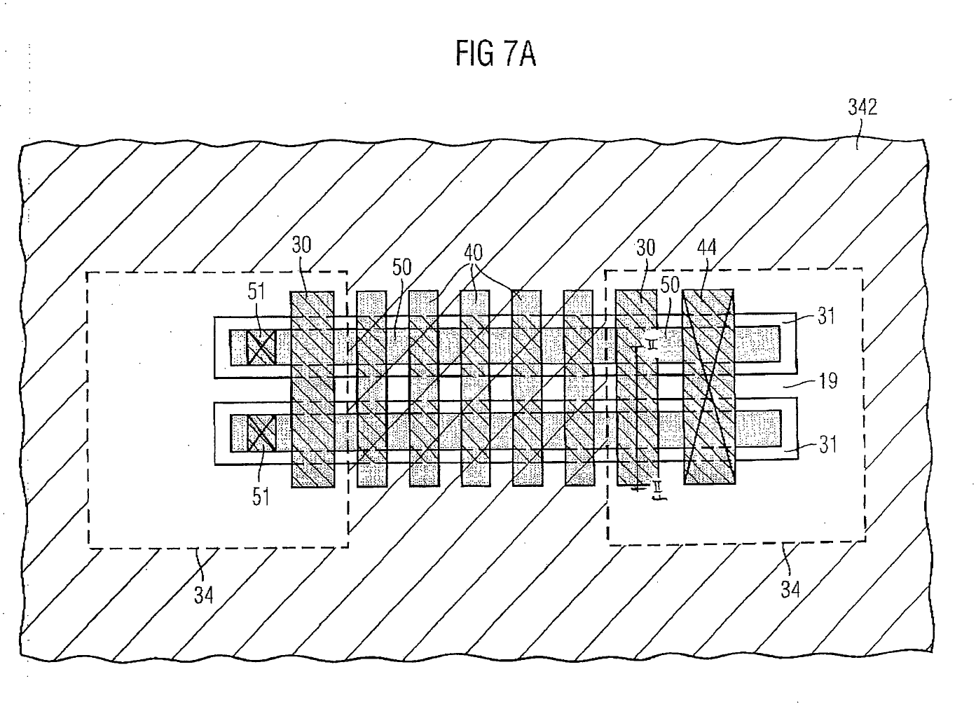

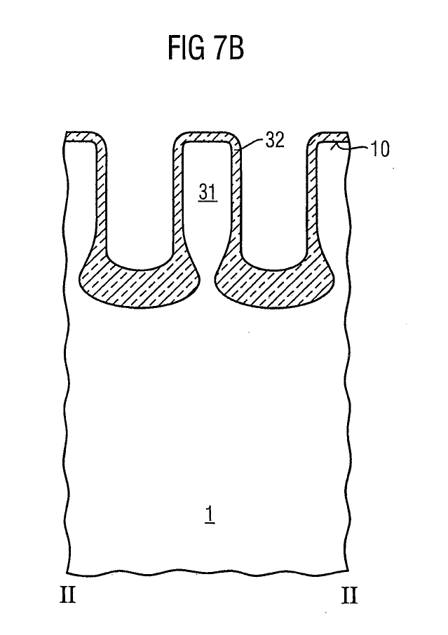

As is shown for example in FIG. 7A, at the edges of each of the active regions 31, select transistors are provided, in contrast to the individual storage cells 20. The select transistors 30 are similarly constructed as the storage cells 20 but comprise a gate oxide 32 instead of the storage layer stack 26. Accordingly, for replacing the storage layer stack 26 with the gate oxide 32, the whole substrate surface is covered with a block mask leaving predeterminded portions opened. At these predetermined portions the select transistors are to be formed. Accordingly, block mask openings 34 are positioned so as to leave the select transistor portions uncovered. A plan view of the resulting structure is shown in FIG. 7A, wherein the memory cell array is covered with a block mask 342, leaving predetermined portions 34 opened.

For defining the select transistors, thereafter, etching steps for removing the storage layers are performed, so as to remove the storage layers from the exposed portions. In particular, the storage layer stack 26 is removed. After removing the photoresist material, in the exposed portions a gate oxide layer is grown by generally known methods. For example, a gate oxide layer 32 having a thickness of approximately 3 to 8 nm is deposited on the exposed surface. The resulting structure is shown in FIG. 7B. As can be seen from FIG. 7B, a gate oxide layer 32 is deposited so as to cover each of the active regions 31 of the select transistors.

Thereafter, a gate stack is deposited on the entire surface. For example, the gate stack may comprise a polysilicon layer 41 which is deposited having a thickness so as to planarize the surface and, in particular, the fin isolation grooves. Thereafter, a metal layer stack is deposited, the metal layer stack 42 having a thickness of approximately 30 to 50 nm. For example, the metal layer may comprise a bottom titanium layer, followed by a TiN layer, followed by a tungsten nitride layer and a tungsten layer. On top of the metal layer stack, for example, a cap layer made of Si3N4 or any other hardmask material may be deposited. For example, the Si₃N₄ cap layer 43 may have a thickness of 40 nm. Nevertheless, as is clearly to be understood, the gate stack may comprise any other layers having arbitrary thicknesses chosen in accordance with the requirements of the memory device.

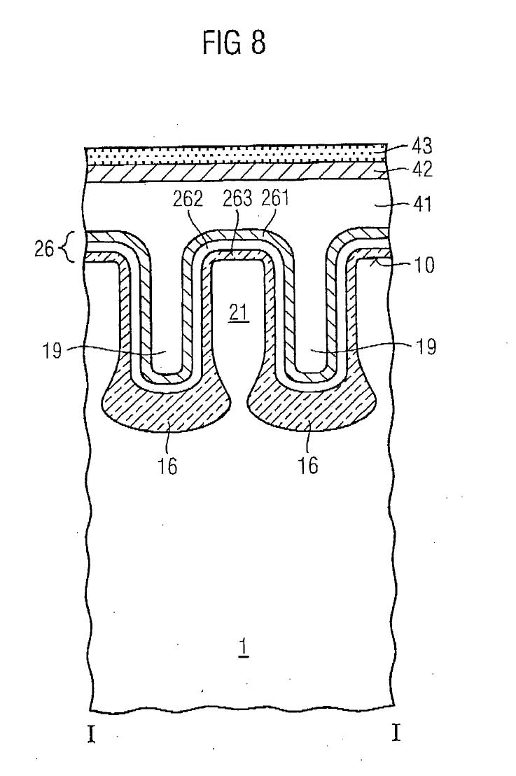

The resulting structure is shown in FIG. 8. As can be seen, each of the active regions 21 is covered with a storage layer stack 26, followed by a gate stack comprising a polysilicon layer 41, a metal layer stack 42 and a hardmask layer 43. For example, the polysilicon layer 41 may have a thickness of approximately 20 to 50 nm when measured from the topmost portion of the storage layer stack 26.

In the next step, the wordlines are patterned so as to extend in a direction which is parallel to the plane of the cross-sectional view shown in FIG. 8. Accordingly, in a first step, a photoresist material is deposited on the structure shown in FIG. 8, and is patterned using a mask having a lines/spaces pattern. Accordingly, stripes of a photoresist material are formed on the substrate surface. Then, the exposed portions of the gate stack are etched using commonly known etching methods. For example, a partial reactive ion etching step may be performed so as to remove the gate stack, in particular, the cap layer 43, the metal layer stack 42 as well as the polysilicon layer 41.

For example, this etching step is time-controlled so as to stop on top of the upper layer of the storage layer stack 26. As a further example, this etching step can as well stop on any layer of the storage layer stack, for example, on top of the bottom layer 263.

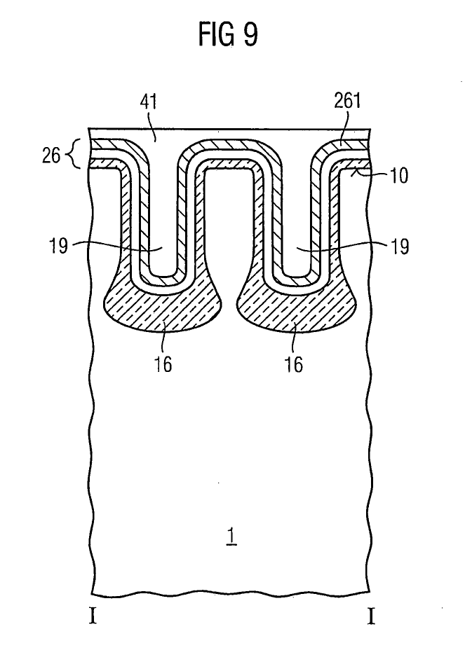

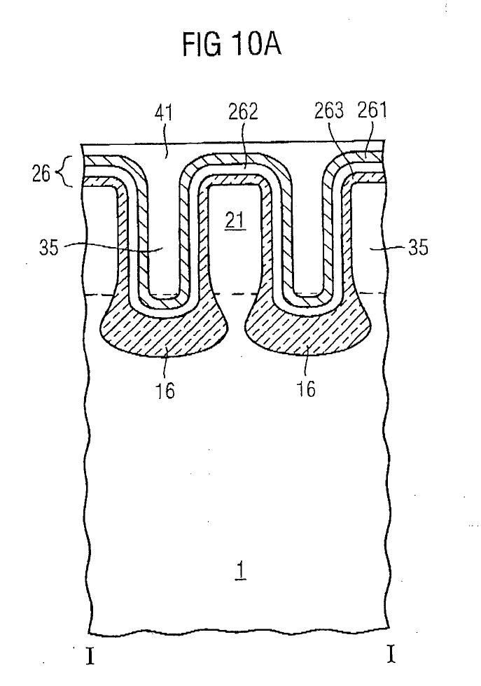

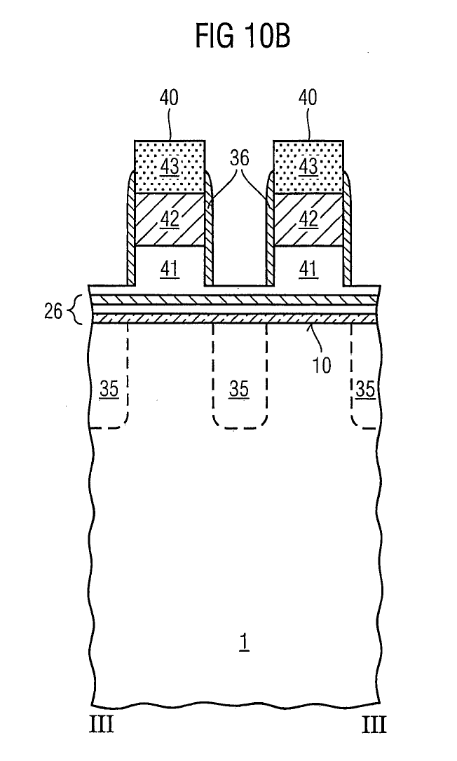

The resulting structure is shown in FIG. 9. In particular, the cross-sectional view shown in FIG. 9 shows a cross-sectional view which is taken under a portion which is not covered with a photoresist material. Accordingly, the polysilicon layer 41 is recessed so that nearly the top layer of the storage layer stack 26, for example, the top layer 261 is exposed. As can further be seen from FIG. 9, the polysilicon layer 41 remains in the fin isolation grooves 19. Accordingly the fin isolation grooves—or at least the upper portions thereof—are still filled with the poysilicon material. Thereafter, a first and, optionally, a second spacer may be formed so as to cover the sidewalls of the wordlines. For example, a first spacer 36 may be provided so as to encapsulate the tungsten layer. In addition, a second spacer (not shown) may be provided so as to control the lateral extension of the doped portions to be formed. The first and second spacers may be made of silicon nitride. Thereafter, an ion implantation step is performed so as to provide the first and the second source/drain portions. To be more specific, a doped portion is provided in the silicon material which is disposed adjacent to the surface of the structure shown in FIG. 9. Accordingly, the polysilicon layer 41 is doped and the active regions 21 are doped with the ions. Due to the presence of the residual polysilicon material 41 filling the fin isolation grooves 19, the ions are prevented from penetrating into the substrate portion which is disposed below the silicon dioxide material 16. As a result, the doped portion 35 as is shown in FIG. 10A is provided. Due to the presence of the residual polysilicon material 41, the ion implantation step can be performed so that the ions are implanted into a very deep depth. For example, the implantation depth can be approximately 40 to 100 nm, for example 60 to 90 nm.

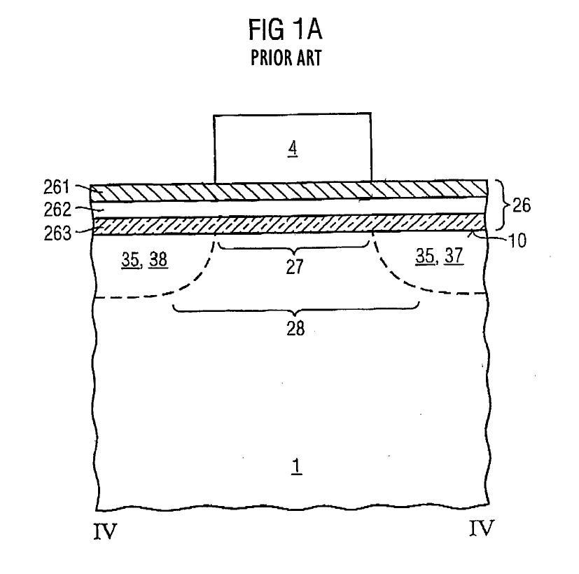

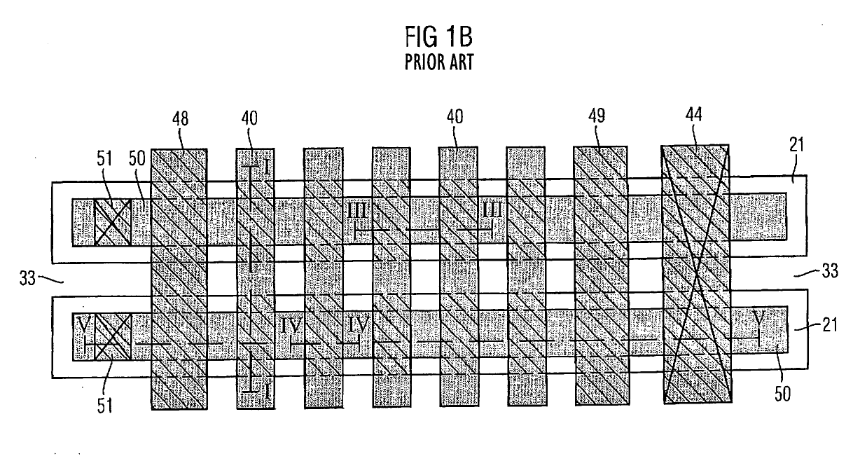

FIG. 10B shows a cross-sectional view which is taken between III and III as can be seen from FIG. 1B. In particular, this cross-sectional view is taken perpendicularly with respect to the wordlines 40. As can be seen, the doped portions 35 are disposed between adjacent wordlines 40. The wordline layer stack prevents the ions from penetrating into the substrate portion which is disposed directly below the wordlines 40. As can be seen from FIG. 10B, the doped portions 35 extend to a very deep depth. In particular, the depth of the doped portion 35 can be approximately 50 to 75 nm, the depth being measured from the top surface of each active regions 21.

Thereafter, further etching steps are performed so as to etch the residual gate material. In particular, in the exposed portions, the remaining polysilicon material 41 is etched, followed by an etching step of etching the upper portion of the storage layer stack. For example, in the example shown, the top silicon nitride layer is etched and the charge trapping layer, i.e., the silicon nitride layer 262 is etched. As a result, the structure shown in FIGS. 11A and 11B is obtained. As can be seen, now the residual polysilicon material as well as the upper layers of the charge storing layer stack are removed from the substrate surface.

FIG. 11B shows a cross-sectional view which is taken perpendicularly with respect to the cross-sectional view shown in FIG. 11A. As can be seen, in FIG. 11B the topmost layers 261, 262 of the storage layer stack are removed from those portions under which the doped portions 35 are defined. A perspective view of the resultant structure is shown in FIG. 12A.

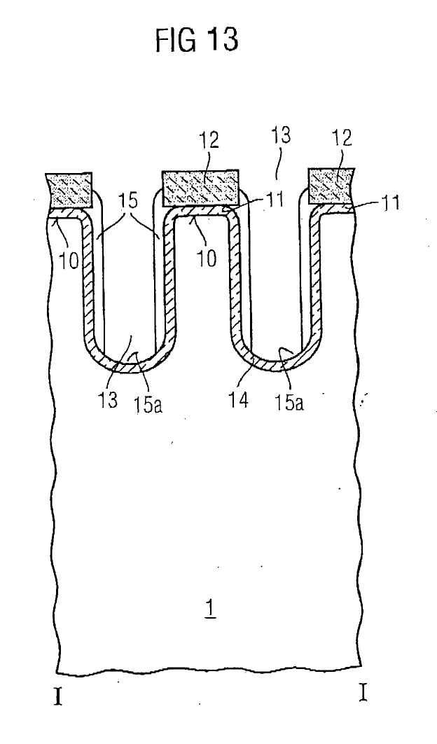

A starting point for performing the second embodiment of the present invention is the structure shown in FIG. 13. The structure shown in FIG. 13 is identical with the structure shown in FIG. 4, and a detailed description of the steps which may be performed in order to obtain the structure shown in FIG. 13 is omitted. As can be seen, in FIG. 13, the surface of the openings 13 is covered with the silicon dioxide layer 14. In the sidewall portions of each of the active regions 21 the silicon dioxide layer 14 is covered with the silicon nitride spacer 15.

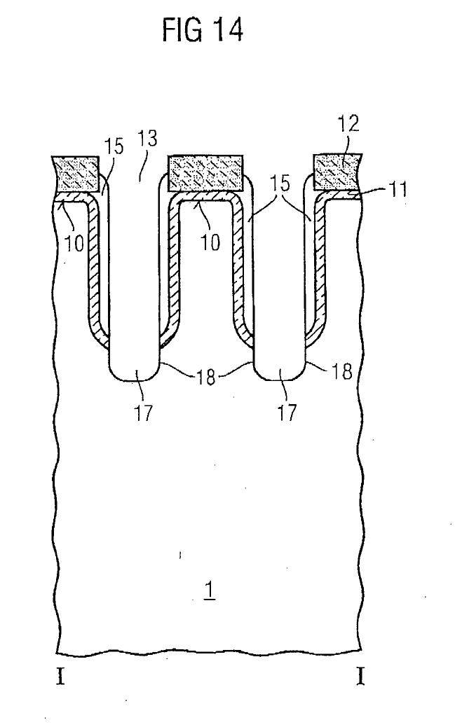

In the next step, an extended opening 17 is formed at the bottom portion of each of the openings 13. To this end, first an etching step for etching silicon dioxide selectively with respect to silicon nitride is performed, followed by a silicon etching step. In particular, these etching steps may be reactive ion etching steps. As a result, an extended opening 17 having exposed sidewalls 18 is formed. The resulting structure is shown in FIG. 14.

As can be seen, the bottom portion of each of the extended openings 17 extends to a deeper depth than the bottom portion of the silicon dioxide layer 14 and the silicon nitride spacer 15. In the next step, a thermal oxidation step is performed so as to form a thermal oxide 16 in the bottom portion of each of the openings 13. In particular, since the sidewall portions 18 have been exposed in the previous step, now a thicker silicon dioxide layer 16 can be grown. For example, the silicon dioxide material can have a thickness of approximately 40 to 60 nm.

As an alternative, the silicon dioxide layer 16 may be provided by a selective oxide deposition method followed by a thermal oxidation step. For example, in such a selective oxide deposition method, a silicon dioxide layer is only deposited on a silicon surface. By way of example, such a method may be a chemical vapour deposition method using for example, TEOS (tetraethylorthosilicate), OMTC (octamethylcyclotetrasiloxan) or HMDS (hexamethyldisiloxan) with added ozone as a precursor. Such an ozone-activated deposition method deposits silicon dioxide on silicon surfaces only. After depositing the silicon dioxide layer 16, a thermal oxidation step is performed so as to react the surface portion of the silicon substrate 1. Due to these process steps the advantage is obtained that a silicon oxide layer 16 having less strain and stress is formed.

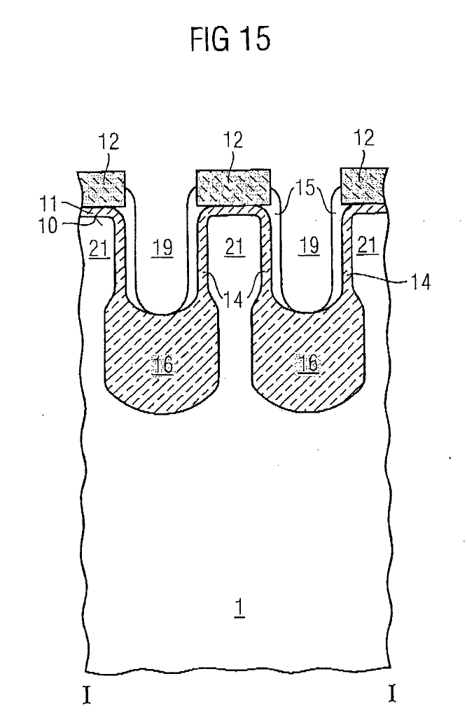

The resulting structure is shown in FIG. 15. As can be seen, adjacent active regions 21 are isolated from each other by a fin isolation groove 19 having a thick silicon dioxide layer in the bottom portion thereof. After defining and filling the fin isolation grooves 19, the silicon nitride layers 12, 15 are removed, for example by wet etching. Thereafter, optionally, implantation steps for providing certain well and/or channel dopings may be performed. Thereafter, the silicon dioxide layer 14 is removed from the surface. Optionally, further thermal oxidation steps may be performed, followed by a step of removing the grown oxide layer, so as to obtain a thinner active region 21. For example a sacrificial layer (not shown) having a thickness of approximately 3 nm may be grown and removed. Thereby, in addition, crystal damages are removed.

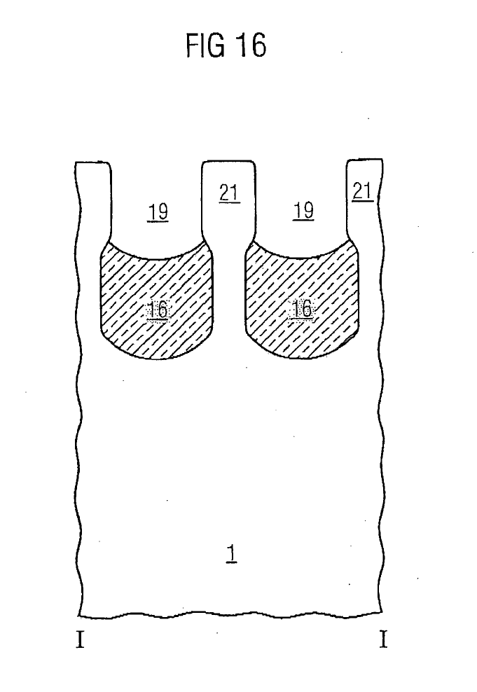

As a result, the structure shown in FIG. 16 is obtained. As can be seen, adjacent active regions 21 having the shape of a ridge are isolated from each other by fin isolation grooves which are filled with an insulating material in the bottom part thereof. In the next steps, the storage layer stack 26 which may be the same as in the first embodiment is deposited. For example, a layer stack comprising a bottom silicon dioxide layer, followed by a silicon nitride layer acting as a charge trapping layer, followed by a top silicon dioxide layer may be deposited.

Thereafter, in a similar manner as has been described before with reference to FIGS. 7A and 7B, the storage layer stack is removed from those portions at which the select transistors are to be defined and a gate oxide layer 32 is defined in the select transistor portions. Thereafter, the gate stack is deposited. For example, the gate stack may comprise a bottom polysilicon layer 41, followed by the metal layer or metal layer stack 42 and a cap layer 43, for example a silicon nitride cap layer. Thereafter, the wordlines are patterned in a similar manner as has been described before with reference to FIGS. 9 to 12. Moreover, the doped portions are provided so as to provide the first and second source/drain regions.

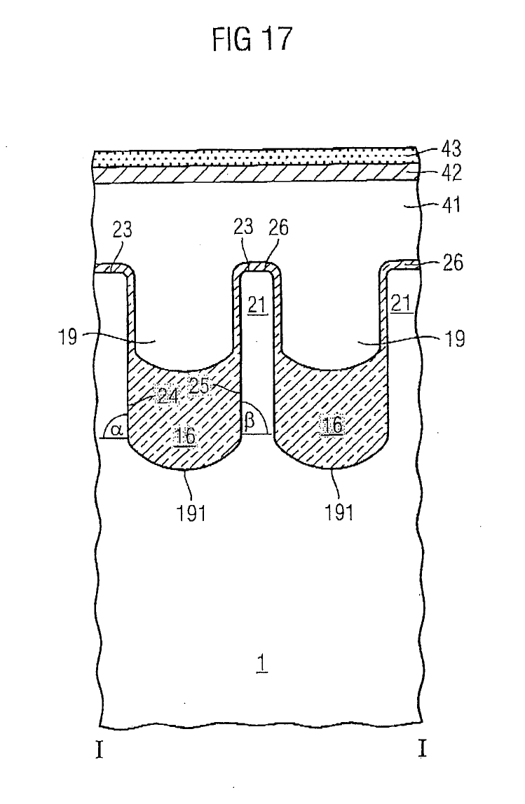

A cross-sectional view of the resulting structure is shown in FIG. 17. As can be seen, adjacent to the active regions 21, the gate layer stack is provided. As can further be seen, the sidewalls of each of the active regions is perpendicularly with respect to the substrate surface.

As is shown in FIG. 17, according to the second embodiment, the thickness of the silicon dioxide layer 16 filling the bottom portion of the fin isolation grooves is very thick when compared with the depth of the fin isolation grooves 19. In particular, the distance di from the upper surface of the ridges to the top surface of the silicon dioxide layer is at least 0.5×dg, wherein dg denotes the distance from the upper surface of each of the ridges to the bottom side of the fin isolation groove 19. Moreover, the distance di is less than 0.7×dg.

According to a third embodiment of the present invention, the steps which have been described with reference to FIGS. 13 to 16 are performed. Starting from the structure shown in FIG. 16, an annealing step is performed in hydrogen. In particular, this annealing step is performed at a temperature of approximately 800° C. for typically one minute. As a result, the upper edges of an active region 21 are shaped so as to have a round or circular form. In particular, as a result of minimizing the surface energy, during this annealing step, the silicon material is rounded so as to obtain active regions 21 having a rounded or circular cross-section.

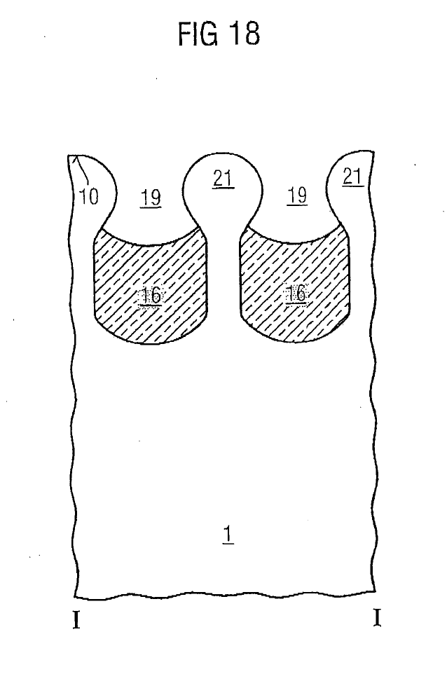

The resulting structure is shown in FIG. 18. As can be seen, the active regions 21 have a rounded or circular shape in the upper portion thereof. Moreover, adjacent active regions 21 are isolated from each other by a fin isolation groove 19 which is filled with an insulating material 16 in the bottom portion thereof. In the next step, the usual process steps for completing a memory device are performed. In particular, a storage layer stack is deposited in a similar manner as has been described above.

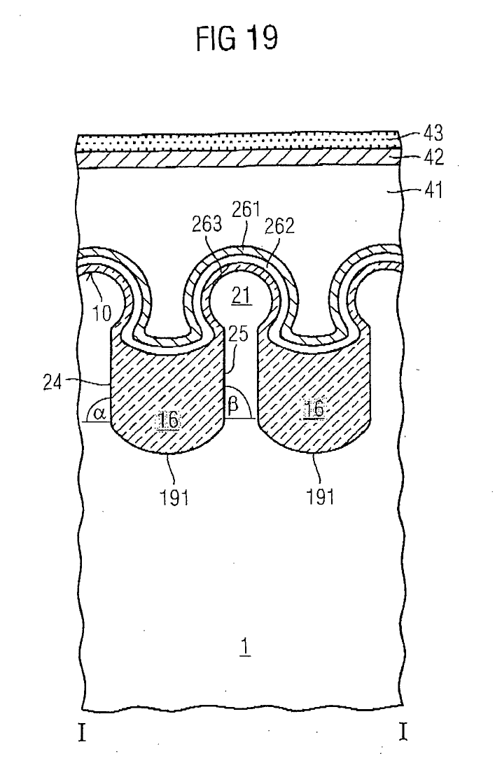

Thereafter, the storage layer stack 26 is removed from predetermined portions at which select transistors 30 are to be formed. At those portions, instead of the storage layer stack 26, a gate oxide layer is thermally grown. Thereafter, a gate stack comprising for example, a polysilicon layer, a metal layer stack 42 and a cap nitride layer 43 is deposited. A cross-sectional view of the resulting strucure is shown in FIG. 19. Finally, the wordlines are defined in a manner as has been described above, and implantation steps for providing the first and second source/drain regions are performed.

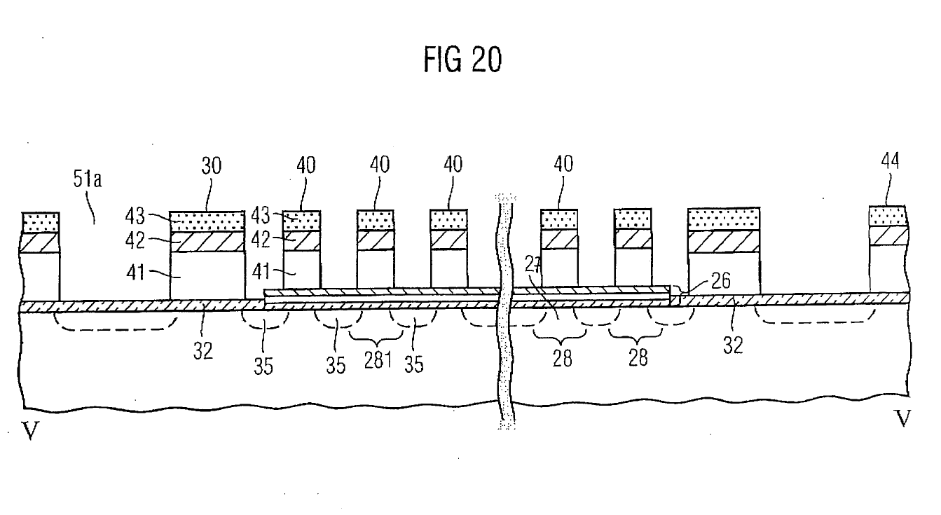

FIG. 20 shows a cross-sectional view between V and V of a memory device according to the present invention. As can be seen, a plurality of transistors are connected in series. For reading out information which is stored in a specific transistor 281 all the transistors 28 of a certain storage cell string have to be properly addressed so as to be in an on-mode. A specific storage cell string is selected by activating a corresponding select transistor.

As is clearly to be understood from the foregoing, the memory device of the present invention can be implemented in arbitrary array configurations. In particular, the invention may be practized in the form of a non-volatile memory cell array comprising a NAND-structure. As an alternative, the invention may as well be practized in a NOR-architecture.

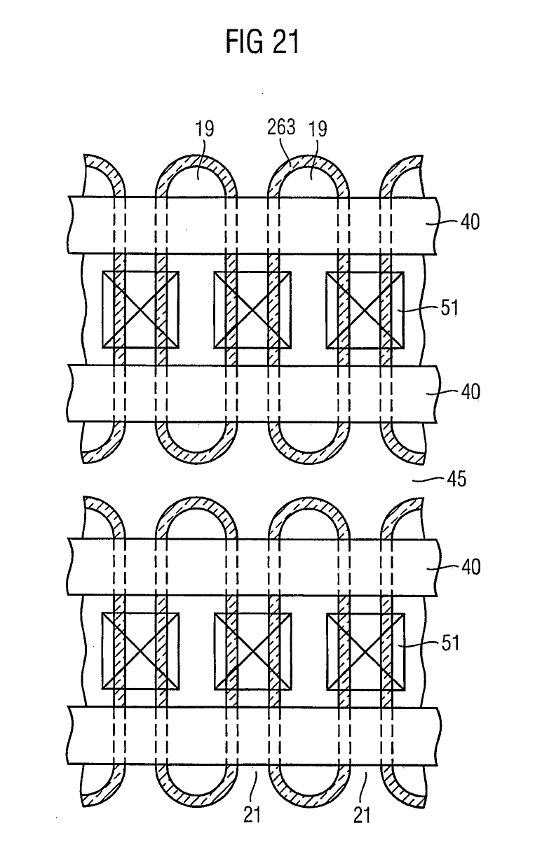

In the following, a description of a NOR-type nonvolatile memory according to the present invention will be given. In particular, a plan view of such a NOR-type nonvolatile memory device is shown in FIG. 21. As can be seen, a plurality of active regions 21 are defined. Fin isolation grooves for isolating adjacent regions 21 are provided. In contrast to the fin isolation grooves 19 which are shown in FIG. 7A, for example, the fin isolation grooves 19 shown in FIG. 21 are not implemented as continuous grooves but as islands. In particular, the fin isolation grooves 19 have an elongated shape. To be more specific, the fin isolation grooves 19 of one column are separated from each other by a doped substrate portion 45 forming the source line. Moreover, wordlines 40 are formed so as to perpendicularly intersect the fin isolation grooves 19. Accordingly, in each of the active regions 21 two adjacent memory cells are formed, one side of the storage transistors forming part of the source line 45, the other part of the storage transistor being connected to a bit line contect 51. In other words, two adjacent storage transistors share one common bit line contact 51 and two adjacent storage transistors share one common source line 45.

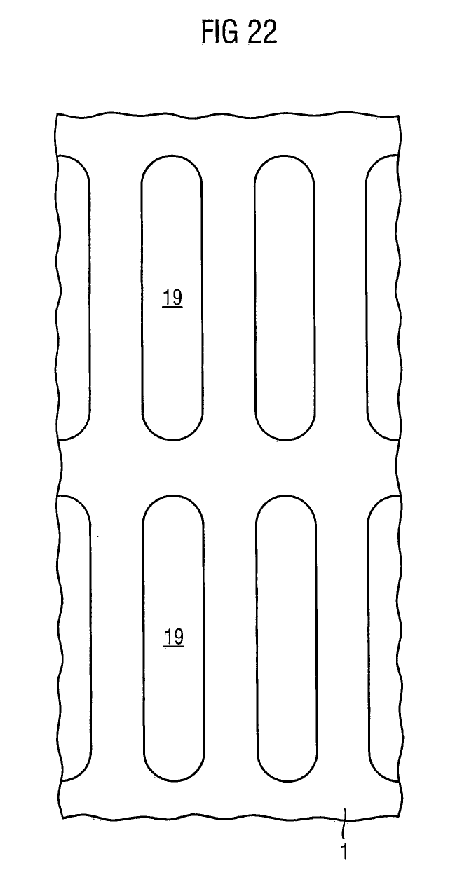

For implementing the structure shown in FIG. 21, first, fin isolation grooves 19 are formed in the manner which has been described above with reference to FIGS. 3 to 6. As an alternative, also the process steps which have been described with reference to FIGS. 13 to 17 or which have been described with reference to FIGS. 18 to 19 may be performed. Nevertheless, for defining the isolation grooves 19, a mask comprising a pattern of elongated holes is taken. Accordingly, the fin isolation grooves 19 having the shape of segments of lines is formed as is shown in FIG. 22. As can be seen from FIG. 22, the fin isolation grooves 19 are arranged in the form of a regular grid, i.e., the fin isolation grooves 19 are disposed in rows and columns.

Thereafter, the further processing steps, for example, being described with reference to FIGS. 8 to 11B are performed. In particular, ion implantation steps are performed so as to provide the doped portions forming the source and the drain portions. In particular, the source line 45 is formed.

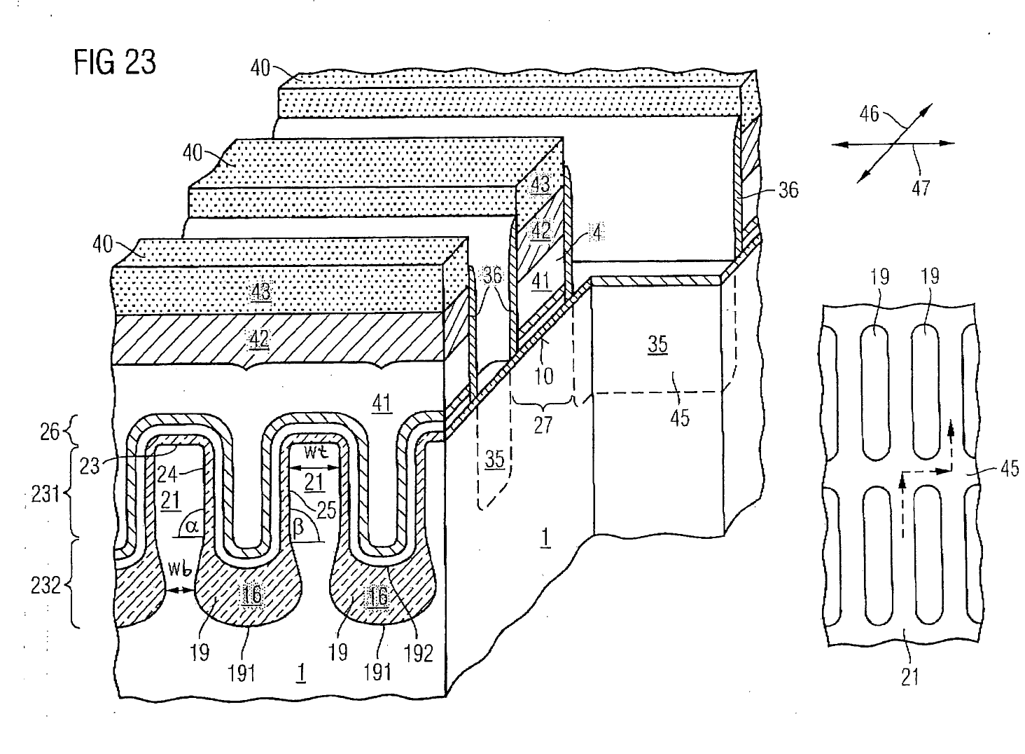

FIG. 23 shows a perspective view of the resulting memory device, in which, for the sake of simplicity, the bitline contacts and planarizing layers between adjacent wordlines are omitted. The insert in the righthand portion of FIG. 23 illustrates the directions along which the various cross-sectional views are taken. As can be seen, in the surface 10 of a semiconductor substrate 1 a plurality of active regions 21 are formed. The active regions 21 have the shape of a ridge. Adjacent ones of the active regions 21 are isolated from each other by fin isolation grooves 19. The fin isolation grooves 19 are filled with silicon dioxide 16 in the bottom portion thereof. Above the silicon dioxide layer 16, a charge trapping layer 262 as well as a top layer 263 of the charge storage stack are disposed. Word lines 40 are formed so as to extend in the second direction 47. Between adjacent word lines 40, doped portions 35 are provided in the active regions 21. A channel 27 is formed between adjacent doped portions 35. The conductivity of the channel 27 is controlled by the corresponding gate electrode 4.

In the embodiment shown in FIG. 23, the fin isolation grooves are implemented as elongated holes. More specifically, they are not formed as continous grooves but as segments of grooves. As can be seen, each of the ridges shown in FIG. 23 has a top portion 231 and a bottom portion 232. The bottom portion 232 is disposed beneath the top portion 231. The top portion has a maximum width wt and the bottom portion have a minimum width wb, measured in a direction perpendicularly to the first direction, respectively. The maximum width wt of the top portion is larger than the minimum width wb of the bottom portion. Similar to the structure shown in FIG. 12B, the depth dg of each of the fin isolation grooves 19 may, for example, be 90 to 200 nm, for example 90 to 130 nm. The depth dg is measured from the upper surface 23 of each of the ridges to the bottom surface 191 of the fin isolation groove 19. For example, the top surface 192 of the insulating material of the fin isolating grooves may be disposed at a depth di, wherein di>0.5×dg, the depth dg being measured from the upper surface 23 of each of the ridges, the fin isolating groove having a depth dg which is measured from the upper surface 23 of each of the ridges to the bottom surface 191 of each of the ridges. For example, the doped portions 35 may extend from the upper surface 23 of each of the ridges to a depth ds, wherein ds>0.3×dg. For example, the depth ds may be more 0.6×dg. For example, the doped portion may extend from the upper surface 23 of each of the ridges at least to a depth ds at which the width of the ridge 21 is decreasing.

As is also shown in FIG. 23, each of the ridges comprises a righthand and a lefthand sidewalls, wherein an angle α between the righthand sidewall 24 and the substrate surface 10 is 90° or less, wherein the angle α is measured in the upper half portion of the ridge. Moreover, an angle β between the lefthand sidewall 25 and the substrate surface 10 may be 90° or more, the angle β being measured in the upper half portion of each of the ridges. In this respect, the height of the ridge is measured from the bottom surface of the fin isolation groove to the upper surface 23 of the ridge. The upper half portion of the ridge refers to the portions which is disposed at a height of more than 0.5× the height of the ridge, measured from the upper surface 23 of the ridge. As can also be seen from FIG. 23, each of the ridges 21 comprises an upper surface 23 and two sidewalls 24, 25 in a cross section, which is taken perpendicularly with respect to the first direction 26. In the same manner as in FIG. 12B, each of the sidewalls 24, 25 comprises at least one curved surface having a center of curvature 193 which lies within the semiconductur substrate in a plane which is taken perpendicularly with respect to the substrate surface 10 and perpendicularly to first direction 26.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### REFERENCE NUMBERAL LIST:

1 semiconductor substrate
10 substrate surface
11 SiO2 layer (pad oxide)
12 Si3N4 layer (pad nitride)
13 opening
14 sacrificial oxide layer
15 Si3N4 spacer
15a exposed surface portion
16 SiO2
17 extended opening
18 exposed sidewall
19 fin isolation groove
191 bottom surface of fin isolation groove
192 top surface
193 center of curvature
20 storage cell
21 active region
22 ridge
23 upper surface of the ridge
231 upper ridge portion
232 lower ridge portion
24 righthand sidewall
25 lefthand sidewall
26 storage layer stack
261 top layer
262 storage layer
263 bottom layer
27 channel
28 transistor
281 selected transistor
30 select transistor
31 active region (select transistor)
32 gate oxide
33 shallow trench isolation
342 block mask
34 block mask opening
35 doped portion
36 spacer
37 first source/drain portion
38 second source/drain portion
4 gate electrode
40 word line
41 polysilicon layer
42 metal layer
43 hardmask layer
44 common source line
45 Source line
46 first direction
47 second direction
48 string selection line
49 ground selection line
50 bitline
51 bitline contact
51a bitline contact opening

What is claimed:

1. A memory device comprising:
a plurality of active regions formed in a semiconductor substrate and extending in a first direction, wherein adjacent active regions are isolated from each other by fin isolation grooves;
a plurality of transistors formed in the active regions, each of the transistors comprising a first source/drain region and a second source/drain region, a channel formed between the first and the second source/drain region, a gate electrode, and a charge storage layer stack disposed between the gate electrode and the channel; and
a plurality of wordlines extending in a second direction that intersects the first direction, wherein each wordline is connected with a plurality of gate electrodes that are assigned to different active regions;
wherein:
the active regions are formed as ridges in the semiconductor substrate, and word lines and charge storage layer stacks are disposed adjacent to at least two sides of corresponding active regions; and
each of the ridges includes a top portion and a bottom portion disposed beneath the top portion, the top portion having a maximum width measured in a direction perpendicular to the first direction, the bottom portion having a minimum width measured in a direction perpendicular to the first direction, and the maximum width of the top portion is larger than the minimum width of the bottom portion.

2. The memory device of claim 1, wherein the charge storage layer stack comprises a tunneling layer, a charge trapping layer and a top layer.

3. The memory device of claim 2, wherein the tunneling layer comprises silicon dioxide.

4. The memory device of claim 2, wherein the charge trapping layer comprises silicon nitride.

5. The memory device of claim 1, wherein the width of each of the ridges is larger in the top portion than in the bottom portion.

6. The memory device of claim 1, wherein each ridge includes a circular cross-section in the top portion.

7. The memory device of claim 1, wherein each of the ridges includes a height dg that is measured from a lower surface of the fin isolation groove to an upper surface of the ridge, and the top portion of each of the ridges extends from half of the height dg to the upper surface of the ridge.

8. The memory device of claim 1, wherein each of the fin isolation grooves has a depth dg of 90 to 200 nm, the depth dg being measured from an upper surface of each of the ridges.

9. The memory device of claim 1, wherein each of the fin isolation grooves has a depth dg of 90 to 130 nm, the depth dg being measured from an upper surface of each of the ridges.

10. The memory device of claim 1, wherein a bottom portion of each of the fin isolation grooves is filled with an insulating material.

11. The memory device of claim 10, wherein a top surface of insulating material of the fin isolation grooves is disposed at a depth di, the depth di being measured from an upper surface of each of the ridges, the fin isolation groove has a depth dg that is measured from the upper surface of each of the ridges, and di>0.5×dg.

12. The memory device of claim 1, wherein the first and second source/drain regions extend from an upper surface of each of the ridges to a depth ds, the fin isolation groove has a depth dg that is measured from the upper surface of each of the ridges, and where ds>0.3×dg.

13. The memory device of claim 12, wherein the first and second source/drain portions extend to a depth ds, where ds>0.6×dg.

14. A memory device comprising:
a plurality of active regions formed in a semiconductor substrate and extending in a first direction, wherein adjacent active regions are isolated from each other by fin isolation grooves;
a plurality of transistors formed in the active regions, each of the transistors comprising a first source/drain region and a second source/drain region, a channel formed between the first and the second source/drain regions, a gate electrode, and a charge storage layer stack disposed between the gate electrode and the channel; and
a plurality of wordlines extending in a second direction that intersects the first direction, wherein each wordline is connected with a plurality of gate electrodes that are assigned to different active regions;
wherein:
the active regions are formed as ridges in the semiconductor substrate, and word lines and charge storage layer stacks are disposed adjacent to at least two sides of corresponding active regions;
each of the ridges comprises a righthand sidewall and a lefthand sidewall, an angle α is defined between the righthand sidewall of each ridge and the substrate surface that is no greater than 90°, the angle α being measured in an upper half of the ridge, an angle β is defined between the lefthand sidewall of each ridge and the substrate surface that is at least 90°, the angle β being measured in the upper half of the ridge, and a height of each ridge is measured from a bottom surface of the fin isolation groove to an upper surface of the ridge.

15. The memory device of claim 14, wherein a bottom portion of each of the fin isolation grooves is filled with an insulating material.

16. The memory device of claim 14, wherein the first and second source/drain regions extend from the upper surfaces of the ridges to a depth ds, the fin isolation grooves have a depth dg that is measured from the upper surfaces of the ridges, and ds>0.3×dg.

17. The memory device of claim 16, wherein the first and second source/drain portions extend to a depth ds, wherein ds>0.6×dg.

18. A memory device comprising:
a plurality of active regions formed in a semiconductor substrate and extending in a first direction, wherein adjacent active regions are isolated from each other by fin isolation grooves;
a plurality of transistors formed in the active regions, each of the transistors comprising a first source/drain region and a second source/drain region, a channel formed between the first and the second source/drain regions, a gate electrode, and a charge storage layer stack disposed between the gate electrode and the channel; and
a plurality of wordlines extending in a second direction that intersects the first direction, wherein each wordline is connected with a plurality of gate electrodes that are assigned to different active regions;
wherein:
the active regions are formed as ridges in the semiconductor substrate, and word lines and charge storage layer stacks are disposed adjacent to at least two sides of corresponding active regions;
each of the ridges comprises an upper surface and two sidewalls extending in a cross-sectional direction that is perpendicular to the first direction; and
each of the sidewalls comprises at least one curved surface having a center of curvature extending within the semiconductor substrate in a plane that is perpendicular to the substrate surface and perpendicular to the first direction.

19. The memory device of claim 18, wherein a bottom portion of each of the fin isolation grooves is filled with an insulating material.

20. The memory device of claim 18, wherein the first and second source/drain regions extend from the upper surfaces of the ridges to a depth ds, the fin isolation grooves have a depth dg that is measured from the upper surface of each of the ridges, and ds>0.3×dg.

21. The memory device of claim 20, wherein the first and second source/drain regions extend to a depth ds, and ds>0.6×dg.

22. A memory device comprising:
a plurality of active regions formed in a semiconductor substrate and extending in a first direction;
a plurality of transistors formed in the active regions, each of the transistors comprising a first source/drain region and a second source/drain region, a channel formed between the first and the second source/drain regions, a gate electrode and means for changing the threshold voltage of the transistor by storing a charge;
means for addressing the gate electrodes; and
means for isolating adjacent active regions from each other;
wherein each of the active regions comprises means for enlarging the width in an upper portion of the active region with respect to the width in a lower portion of the active region.

23. The memory device of claim 22, wherein the means for isolating adjacent active regions from each other includes fin isolation grooves, and an insulating material filled in a lower portion of the fin isolation grooves.

24. A method of forming a memory device, comprising:
providing a semiconductor substrate including a surface;
providing grooves extending in a first direction of the substrate that define active regions, each of the grooves comprising sidewalls and a bottom portion;
covering the sidewalls of the grooves with a cover layer;
providing an insulating layer on the bottom portion of each of the grooves;
removing the cover layer from the sidewalls of the grooves;
providing a storage layer stack that is adjacent the sidewalls of the grooves and the surface of each of the active regions, the storage layer stack covering the insulating layer;
providing a word line layer stack comprising at least one conductive layer;
patterning the word line layer stack and the storage layer stack so as to form individual word lines and uncovered portions of the active regions; and
providing doped portions in each of the active regions so as to form first and second source/drain regions.

25. The method of claim 24, wherein the insulating layer is provided on the bottom portion of each of the grooves via a process comprising thermal oxidation.

26. The method of claim 25, wherein the insulating layer is further provided on the bottom portion of each of the grooves by performing a deposition method that selectively forms an insulating layer on an uncovered substrate portion, and the deposition method is performed before thermal oxidation.

27. The method of claim 24, wherein providing doped portions in each of the active regions comprises performing an ion implantation process using the patterned word lines as an implantation mask.

28. The method according to claim 24, wherein patterning the word line layer stack and the storage layer stack comprises performing a first sequence of etching steps and a second sequence of etching steps, the doped portions are provided by an ion implantation process that is performed after performing the first sequence of etching steps, and the second sequence of etching steps is performed after the ion implantation process.

29. A method of manufacturing a NAND-type non-volatile memory device comprising performing the method of claim 24, wherein the storage layer stack further comprises a charge trapping layer and a top layer, and the method further comprises:
removing the charge trapping layer and the top layer from selected portions of each of the active regions.

30. The method of claim 29, wherein removing the charge trapping layer and the top layer from portions of each of the active regions comprises providing a block mask that leaves the selected portions of the active regions uncovered, and etching the top layer and the charge trapping layer in the uncovered regions.
